(19) United States
(12) Patent Application Publication
(10) Pub. No.: US 2025/0054752 A1
(43) Pub. Date: Feb. 13, 2025

(54) METHOD TO SMOOTH SIDEWALL ROUGHNESS AND MAINTAIN REENTRANT STRUCTURES DURING DIELECTRIC GAP FILL

(71) Applicant: Lam Research Corporation, Fremont, CA (US)

(72) Inventors: Dustin Zachary Austin, Tigard, OR (US); Joseph R. Abel, West Linn, OR (US)

(21) Appl. No.: 18/720,198

(22) PCT Filed: Dec. 15, 2022
(86) PCT No.: PCT/US2022/081636

§ 371 Date: Jun. 14, 2024

Related U.S. Application Data
(60) Provisional application No. 63/265,631, filed on Dec. 17, 2021.

(51) Int. Cl. H01L 21/02; C23C 16/02; C23C 16/04; C23C 16/40; C23C 16/455; C23C 16/56

(52) U.S. Cl. CPC H01L 21/0228; C23C 16/0245; C23C 16/045; C23C 16/402; C23C 16/45536; C23C 16/56; H01L 21/02164; H01L 21/02274

(57) ABSTRACT

Methods of filling a gap with a dielectric material including using an inhibition plasma during deposition. The inhibition plasma increases a nucleation barrier of the deposited film. The inhibition plasma selectively interacts near the top of the feature, inhibiting deposition at the top of the feature compared to the bottom of the feature, enhancing bottom-up fill. The inhibition plasma may also be used to etch portions of the feature to reduce void formation.

### INCORPORATED BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Many semiconductor device fabrication processes involve formation of films including silicon-containing films such as silicon oxide or silicon nitride. Plasma enhanced atomic layer deposition (ALD) may be used to deposit silicon-containing films. Depositing a high-quality film can be particularly challenging when depositing films in gaps. Challenges can include the formation of voids and/or seams in the films.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are methods and systems of depositing films. In one aspect of the embodiments herein, a method for depositing film is provided, the method including: providing a substrate having a structure with a gap; depositing a conformal layer of a first dielectric material in the gap of the structure; and performing a first set of one or more cycles of: exposing the substrate to a plasma including halogen species to etch the first dielectric material on a first portion of the gap; and after (a), depositing a second dielectric material in the gap; and after performing the first set of one or more cycles, depositing additional second dielectric material in the gap.

In some embodiments, during (a) exposing the substrate to a plasma including halogen species inhibits deposition on a second portion of the gap. In some embodiments, depositing the second dielectric material includes a plasma enhanced atomic layer deposition (ALD) process. In some embodiments, depositing additional second dielectric material in the gap includes performing one or more cycles of: exposing the substrate to a plasma including halogen species to inhibit dielectric material on a second portion of the gap; and after exposing the substrate to the plasma including halogen species, depositing second dielectric material in the gap. In some embodiments, the second portion is near the top of the gap.

In some embodiments, the conformal layer is a silicon-containing film. In some embodiments, the conformal layer is an oxide film. In some embodiments, the first dielectric material and the second dielectric material are silicon dioxide. In some embodiments, the plasma including halogen species is generated from fluorine-containing gas. In some embodiments, the plasma including halogen species is generated from nitrogen-containing gas. In some embodiments, the structure includes layers of different materials and the gap are conformally covered by a layer of poly silicon. In some embodiments, the gap has sidewalls having a roughness of at least about 0.5 nm. In some embodiments, exposing the substrate to a plasma including halogen species reduces a roughness of one or more sidewalls of the gap. In some embodiments, the plasma has a power of at least about 250 W per substrate. In some embodiments, the plasma has a power of between about 625 W and about 1500 W per substrate. In some embodiments, a duration of exposing the substrate to the plasma is at least 20 seconds. In some embodiments, the conformal layer is at least about 10 Angstroms thick. In some embodiments, depositing a conformal layer and the performing the first set of one or more cycles are performed in the same chamber. In some embodiments, the gap includes a re-entrant feature. In some embodiments, depositing second dielectric material in the gap includes two or more cycles of an ALD process, wherein at least the first ALD cycle of the two or more cycles etches dielectric material in the second portion of the gap.

In another aspect of the embodiments herein, a method for depositing a film is provided, the method including: providing a substrate having a gap that includes a re-entrant structure; depositing a conformal layer of a first dielectric material in the gap; and performing a first set of one or more cycles of: exposing the substrate to a plasma including halogen species to inhibit deposition on a portion of the gap above the re-entrant structure; and depositing a second dielectric material in the gap, wherein during (b) the portion of the gap above the re-entrant structure is etched. In some embodiments, (a) is performed for between about 0.1 and about 0.2 seconds. In some embodiments, the re-entrant structure has a first portion and a second portion, and a ratio of a width of the first portion and a width of the second portion is at least about 5:1. In some embodiments, a first portion of the re-entrant structure is the narrowest portion of the re-entrant structure, and wherein the first portion is at a height from the bottom of the gap of less than about 50% of the total height of the gap. In some embodiments, (b) includes a plasma enhanced atomic layer deposition (ALD) process. In some embodiments, during (b) halogen species etch dielectric material in the gap but do not etch in the re-entrant structure. In some embodiments, during (a) halogen species are adsorbed on the portion of the gap, and during (b) the adsorbed halogen species etch dielectric material in the gap. In some embodiments, during (b) a plasma is ignited having a power between about 1000 W and about 3000 W. In some embodiments, the method further includes performing a second set of one or more cycles to fill the gap with dielectric material, wherein the second set of one or more cycles is performed after partially filling the re-entrant structure with dielectric material.

These and other features of the disclosed embodiments will be described in detail below with reference to the associated drawings.

### BRIEF DESCRIPTION OF DRAWINGS

FIG. 1 presents a flow diagram of operations for one example embodiment.

FIG. 2 presents an illustration of one example embodiment to smooth sidewalls of features.

FIG. 3 presents a flow diagram of operations for one example embodiment.

FIG. 4 presents a flow diagram of operations for atomic layer deposition processes.

FIG. 5 presents an illustration of one example embodiment to fill features below a reentrancy without pinch off.

FIGS. 6-9 are schematic diagrams of examples of process chambers for performing methods in accordance with disclosed embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often include dielectric gap fill using chemical vapor deposition (CVD) and/or atomic layer deposition (ALD) methods to fill features. Described herein are methods of filling features with dielectric material including but not limited to silicon-containing films such as silicon oxide, and related systems and apparatuses. The methods described herein can be used to fill vertically oriented features formed in a substrate. Such features may be referred to as gaps, recessed features, negative features, unfilled features, or simply features. Filling such features may be referred to as gap fill. Features formed in a substrate can be characterized by one or more of narrow and/or re-entrant openings, constrictions within the feature, and high aspect ratios. In some implementations, a feature may have an aspect ratio of at least about 2:1, at least about 4:1, at least about 6:1, at least about 20:1, at least about 100:1, or greater. The substrate may be a silicon wafer, e.g., a 200-mm wafer, a 300-mm wafer, or a 450-mm wafer, including wafers having one or more layers of material such as dielectric, conducting, or semi-conducting material deposited thereon.

One aspect of the disclosure relates to a method of using an inhibition plasma during atomic layer deposition (ALD) of dielectric material in gaps that facilitates void-free bottom gap fill. The inbibition plasma creates a passivated surface and increases a nucleation barrier of the deposited ALD film. When the inhibition plasma interacts with material in the feature, the material at the bottom of the feature receives less plasma treatment than material located closer to a top portion of the feature or in field because of geometrical shadowing effects. As a result, deposition at the top of the feature is selectively inhibited and deposition in lower portions of the feature proceeds with less inhibition or without being inhibited. As a result, bottom-up fill is enhanced, which creates a more favorable sloped profile that mitigates the seam effect and inhibits void formation. Voids and seams may be used interchangeably herein, and may be used to refer to gaps within a film or a portion within a film that is non-homogenous with the rest of the film, e.g., a lower density portion of the film Halogen-containing plasmas can be effective inhibition plasmas. For example, for some applications, a plasma generated from nitrogen trifluoride (NF₃) may provide an inhibition effect in a substantially reduced time compared to a plasma generated from molecular nitrogen (N₂). Halogen-containing plasmas may also act as an etchant. For example, while performing an inhibition, an atom hitting a surface with low energy can act as an inhibition while a high energy atom can remove material. Because the plasma has an energy distribution, some component of the plasma may hit peaks from the sidewall and etch. The plasma properties may be tuned so that this etch component may be used to facilitate fill. Described herein are methods of filling features with reduced void size and/or formation.

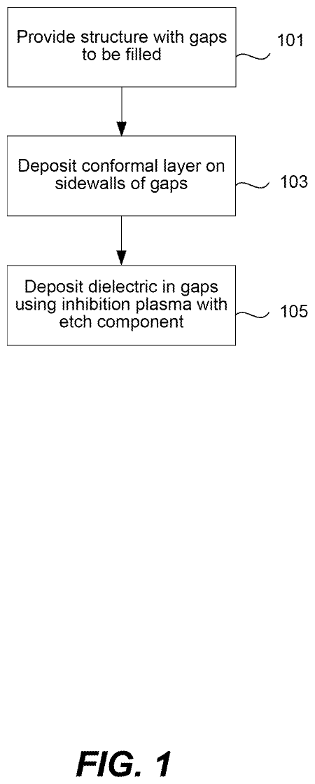

FIG. 1 is a process flow diagram that illustrates a method of filling gaps with dielectric material. The method begins with providing a structure with one or more gaps to be filled (101). The structure may be formed by one or more layers of material deposited on a substrate. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to for gap fill of gaps of other substrates, such as glass, plastic, and the like, including in the fabrication of microelectromechanical (MEMS) devices.

Examples of structures include 3D NAND structures, DRAM structures, field effect transistor (FET) structures, and shallow trench isolation (STI) structures. The structures include gaps with the sidewalls of the gaps formed by a material susceptible to etch and/or having different selectivity for underlying layers. In one example, 3D NAND structure includes oxide-nitride-oxide-nitride (ONON) stacks covered with a poly silicon (poly Si) layer. As the oxide and nitride layers may have different selectivity for depositing the poly Si layer, the poly Si layer may deposit at different rates on each layer, resulting in a roughness that is undesirable and leads to voids and/or seams in filled features. Other examples of sidewall materials include oxides, metals, and semiconducting materials. The methods described herein are not limited to a particular class of sidewall material.

A conformal layer is deposited in the gaps (103). The conformal layer may protect the underlying layer from unwanted etch during a subsequent inhibition plasma. In some embodiments, it may be deposited to a thickness that will protect the underlaying layer during a subsequent process that includes an etch component. In some embodiments, the conformal layer is a silicon nitride layer. In some embodiments, the conformal layer is a silicon oxide layer. In some embodiments, the conformal layer is a metal oxide layer, e.g., titanium oxide, zirconium oxide, tin oxide, hafnium oxide, or combinations thereof. Deposition of the conformal layer by atomic layer deposition (ALD) can result in a conformal layer that has a similar roughness as the underlying poly Si layer.

Once the conformal layer is deposited, a dielectric material is deposited in the gaps using an inhibition chemistry with an etch component (105). As discussed further below, this can involve cycles of inhibition plasma followed by ALD of the dielectric film. In some embodiments, the inhibition plasma may be tuned to have an etch component that smooths the sidewalls by selectively etching peaks of the sidewall roughness. In some embodiments, the inhibition plasma may be tuned to have an etch component in addition to inhibiting portions of the sidewalls. In alternate embodiments, a structure is exposed to a plasma that may have an anisotropic etching component without an inhibition component. The anisotropic etch may smooth the sidewalls. In some embodiments, the inhibition plasma may be used for a target depth etch along with an ALD cycle in an atomic layer etch type etch. The gaps may be filled by a process involving cycles of inhibition plasma followed by ALD of the dielectric material.

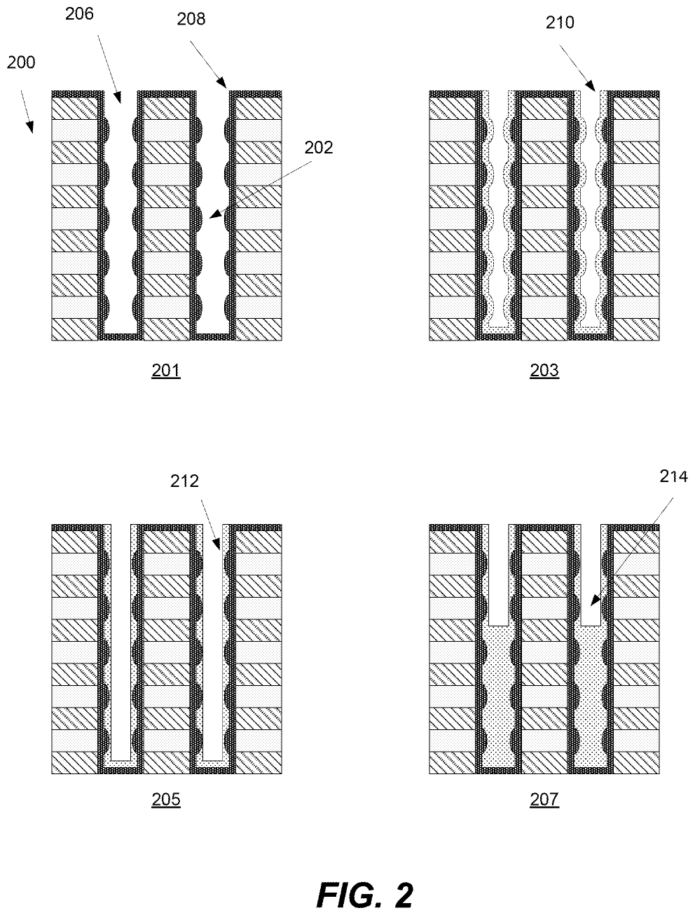

FIG. 2 shows an example of a structure 200 during various stages of a gap fill method described herein. At 201, the structure 200 is shown with gaps 206 to be filled with a dielectric material. In the example of FIG. 2, the gaps 206 are formed between ONON stacks covered with a poly Si layer 208, which forms the sidewalls 204 of the gaps 206. The poly Si layer 208 has a roughness (exaggerated in FIG. 2), which may result in voids and/or seams when the gap is filled. For example, deposition on peak 202 in the poly Si layer 208 may result in a peak in the deposited oxide material on the poly Si layer. Thus, in the absence of techniques as described herein, gap fill in the features may result in voids and/or seams as the peaks from opposite sidewalls join to at pinch-off points, inhibiting fill below the pinch-off points. In FIG. 2 the roughness corresponds with a deposition selectivity between the oxide and nitride layers of the ONON stack, such that the poly Si layer has increased deposition on different portions of the stack, resulting in a roughness and peaks 202. Roughness may be caused by effects other than selective deposition.

At 203, a conformal layer 210 is shown on the poly Si layer 208. The conformal layer is deposited conformally within the gaps of the structure. As the conformal layer may be deposited by a conformal process, the conformal layer 210 has a similar roughness profile as the underlying poly Si layer. In some embodiments, the conformal layer 210 may be at least about 5 angstroms thick or at least about 10 angstroms thick. In some embodiments, the conformal layer 210 may have a thickness at least on the order of the sidewall roughness. In some embodiments, the conformal layer 210 may be about 1 micron thick. This dep and etch can be done cyclically throughout the process to target different depths or unintended added sidewall roughness. In some embodiments the conformal layer 210 may have a thickness that is at least as thick as a height of the roughness profile, such that when the conformal layer 210 is etched back to improve smoothness the underlying poly Si layer is not exposed or etched. In some embodiments, the poly Si layer 208 has a roughness of at least about 0.5 nm, or between about 0.5 nm to about 250 nm.

At 205, the structure is exposed to a plasma, such as an inhibition plasma, having an etch component that etches the conformal layer 210 to form a smooth layer 212. As the plasma ions are substantially anisotropic, the conformal layer 201 is selectively etched at the peak 202 of the sidewall. The peaks 202 shadow the valley portions of the conformal layer 210 such that they are not etched as much as the peaks 202. Smooth layer 212 is thinner at the peaks 202 compared to the valleys, having a thickness that may effectively inverse the roughness of the underlying poly Si layer 208 and reduce the roughness of the conformal layer 210. In the embodiments shown, the conformal layer 210 is etched such that the underlying poly Si layer 208 is not etched. The conformal layer 210 is still present, but is presented as smooth layer 212, having been partially etched by the inhibition plasma to reduce peaks. The inhibition plasma may also inhibit deposition on the sidewalls of the feature in addition to etching.

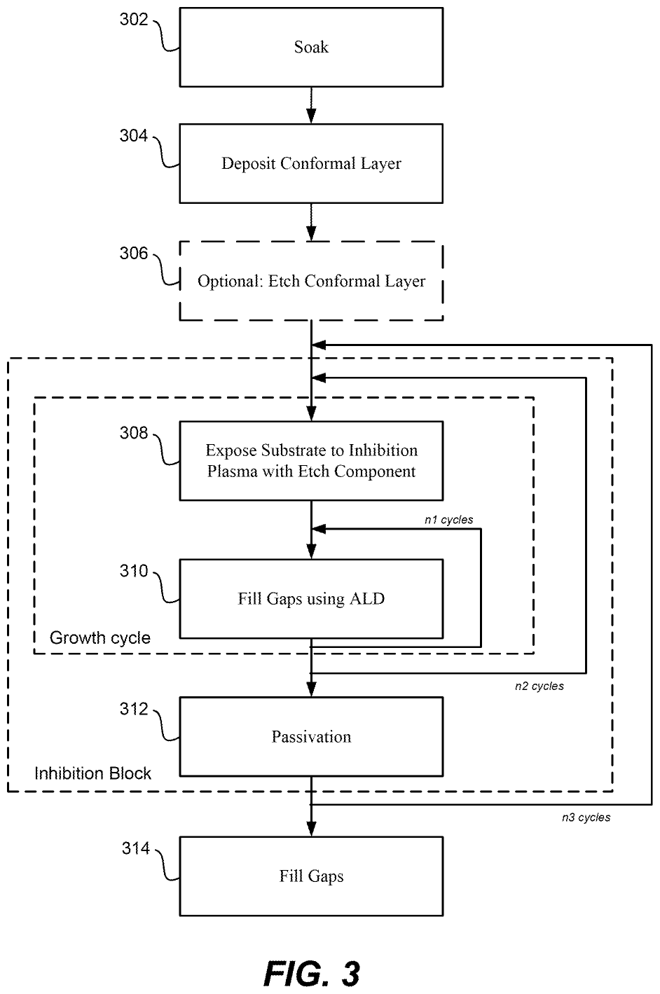

At 207, the gaps 206 are partially filled with dielectric material 214 in a bottom-up manner using an inhibition plasma (as explained in further detail in relation to FIG. 3), such that there is relatively little or no deposition on the poly Si sidewalls above a fill line 216. Further cycles of bottom-up fill may be performed to completely fill the gaps. As the sidewalls have been smoothed by a plasma having an etch component, there are fewer and/or smaller voids, or no voids, present in the deposited dielectric film.

As discussed further below, in some embodiments the substrate is exposed to an inhibition plasma multiple times to inhibit deposition in between multiple cycles of ALD. In some embodiments, sidewall smoothing may be performed using multiple exposure to inhibition plasma, where each exposure further etches and smooths the sidewalls. In such embodiments, a first portion of the sidewall may be etched and inhibited by the inhibition plasma while a second portion of the sidewall is merely inhibited, or is inhibited and etched but etched to a lesser extent. Generally, portions of the sidewall that are closer to the top of the gap may experience greater etching and inhibition than portions of the sidewall that are deeper in the feature.

FIG. 3 shows an example of a process sequence that may be used in accordance with the disclosed embodiments. The process sequence in FIG. 3 includes deposition of a conformal layer prior to exposure to an inhibition plasma. Other operations (e.g., soak 302, passivation 312) may be omitted in certain embodiments and operations may be added in certain embodiments. In the example process sequence of FIG. 3, one or more features on a substrate undergo gap fill. In some embodiments, one or more operations described in FIG. 3 may be performed in a single process chamber or tool. The process may begin with a soak after being provided to a deposition chamber (302). This can be useful, for example, to remove particles or other pretreatment. Then, a conformal layer is deposited in gaps of the substrate. The conformal layer may be deposited by any conformal process, including ALD, CVD, or sputtering, including any plasma enhanced processes. Further details of ALD are discussed below. After the conformal layer is deposited, an optional etch process may be performed (306). In some embodiments the etch process may be a discrete etch to smooth the conformal layer. In some embodiments, the etch process may comprise exposing the substrate to a plasma. In some embodiments block 306 is integrated with an inhibition block, such as block 308, to expose the substrate to an inhibition plasma with an etch component. In some embodiments n inhibition blocks are performed, with the operations of an inhibition block shown. The inhibition plasma is a surface treatment that may include an etch component (308). As discussed above, the plasma may include halogen species including anion and radical species such as F⁻, Cl⁻, I⁻, Br⁻, fluorine radicals, etc. In some embodiments, the plasma is generated from halogen containing gases. In some examples, the halogen-containing gases can include but not limited to nitrogen trifluoride (NF₃). Other inhibition plasmas may be used. For example, plasmas generated from molecular nitrogen (N₂), molecular hydrogen (H₂), ammonia (NH₃), amines, diols, diamines, amino alcohols, thiols or combinations thereof may be used as inhibition plasmas. In some embodiments, gases without a halogen may be combined with halogen-containing gases to have an etch component as discussed herein. In some embodiments, the species flowed into the plasma are capable of etching the dielectric material to be deposited in the gaps in addition to inhibiting deposition.

When the inhibition plasma interacts with material in the feature, the material at the bottom of the feature receives less plasma treatment than material located closer to a top portion of the feature or in the field region because of geometrical shadowing effects. As a result, deposition at the top of the feature is selectively inhibited and deposition in lower portions of the feature proceeds with less inhibition or without being inhibited. Furthermore, the process parameters may be tuned to increase or decrease an etch component of the inhibition plasma. Generally, increasing the RF power used to generate the plasma, the duration of exposing the substrate to the inhibition plasma, and the flow rate of species that are converted to ions or radicals by the plasma will increase an etch component of the inhibition plasma. Increasing these parameters will tune the inhibition plasma to have a stronger etch component in addition to the inhibition component, etching the sidewalls of the features to smooth the conformal layer deposited thereon.

In FIG. 3, the next operation in the inhibition block is n1 cycles of ALD fill (310). The dielectric material is deposited selectively at the bottom of the feature. The inhibition plasma in block 308 and the n1 cycles of ALD fill in block 310 together make a growth cycle, and can be repeated n2 times to continue filling the feature with intermittent inhibition operations when the inhibition effect diminishes. The number of growth cycles in an inhibition block may depend on the re-entrancy of the feature, i.e., if it narrows at one or more points from the bottom to the top of the feature. Features that exhibit more re-entrancy may use a longer inhibition time or multiple inhibition blocks. Alternatively, as discussed further below, a shorter inhibition time and fewer ALD cycles may be used to gradually fill features having re-entrancy. Once the reentrant feature is filled below the re-entrancy, the growth cycles and inhibition blocks may be adjusted to increase the speed of fill to improve throughput. In the example of FIG. 3, the inhibition block ends with a passivation operation (312). The passivation operation 312 is a surface treatment that removes residual inhibitor and can also densify the deposited film. In some embodiments, an oxygen plasma is used. In some embodiments, block 312 may be omitted.

One or more additional inhibition blocks, including growth cycle and passivation, may be performed for a total of 3 inhibition blocks. The number of inhibition blocks depends on how much material is used to fill the feature. Inhibition plasma, ALD, and passivation conditions may be changed from inhibition block to inhibition block to fill the feature. For example, an inhibition plasma duration may be 30 seconds until the bottom quarter of the feature is filled (inhibition block 1), then changed to 10 seconds for the middle 50% of the structure (inhibition block 2), etc. In some embodiments, the duration of an inhibition plasma may be based on the aspect ratio and/or depth of the structure to be filled. In some implementations, the first inhibition block may have a longer inhibition plasma duration and a higher power in order to smooth sidewalls as described above compared to subsequent inhibition blocks. The duration of an inhibition plasma for any inhibition block described herein may be at least about 5 seconds, at least about 10 seconds, at least about 20 seconds, or at least about 30 seconds. In some embodiments, a first inhibition block may include exposing the substrate to an inhibition plasma with an etch component, and a subsequent inhibition block may tune the parameters of the inhibition plasma to decrease or remove the etch component. After one or more exposures to an inhibition plasma with an etch component, the etch component may be unnecessary to further smooth the sidewalls and may decrease the overall rate of fill, which is undesirable.

In some implementations, the inhibition blocks may be divided into two or more sets of blocks. For example, a first set of inhibition blocks may comprise exposing the substrate to an inhibition plasma with an etch component, as described herein. A second set of inhibition blocks may comprise tuning the process parameters, e.g., plasma power, gas flow, and inhibition plasma treatment duration, for the inhibition step to reduce or remove the etch component. The second set of inhibition blocks may be performed after sufficiently etching portions of the features to reduce the formation of voids during the first set of inhibition blocks. The second set of inhibition blocks may generally fill gaps faster than the first set of inhibition blocks, such that the second set of inhibition blocks are preferable once the features have been sufficiently filled or etched during the first set of inhibition blocks, as described herein.

When the feature is nearly filled, inhibition may no longer be necessary, and the fill can be completed without using inhibition (314). In some embodiments, a cap or overburden layer of dielectric may then be deposited. Plasma enhanced chemical vapor deposition (PECVD) may be used at this stage for a fast deposition.

In various embodiments, the inhibition plasma is an in-situ plasma, such that the plasma is formed directly above the substrate surface in the station. In some embodiments the plasma is a capacitively coupled plasma (CCP) Example power for a 4-station chamber for an in-situ plasma may be at least about 1000 W, at least about 2500 W, between about 1000 W and about 6000 W, between about 1000 W and about 3000 W, and between about 2500 W and about 6000 W. Higher power may increase an etching component of the plasma. Example power for a 4-station chamber for an in-situ plasma having an etch component may be at least about 2500 W, between about 1000 W and about 6000 W, between about 1000 W and about 3000 W, and between about 2500 W and about 6000 W. In some embodiments, lower power, e.g., 2500 W, may be used with a longer duration of plasma treatment, e.g., 30 seconds, to etch the substrate. These powers are for a chamber processing four 300 mm wafers; appropriate modification may be made for larger/smaller wafers and/or more/less chambers (e.g., these values may be divided by 4 for a single wafer, such that 1000 W for a four wafer chamber may be about 250 W for a single wafer or about 0.3536 W/cm² per substrate area). Plasmas for ALD processes may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes. Non-limiting examples of electrodes include process gas distribution showerheads and substrate support pedestals. It will be appreciated that plasmas for ALD processes may be formed by one or more suitable methods other than capacitive coupling of an RF field to a gas. In some embodiments, the plasma is a remote plasma, such that second reactant is ignited in a remote plasma generator upstream of the station, then delivered to the station where the substrate is housed.

In some embodiments the ratio of inhibition species to inert gas may be about 1:5, about 1:10 or between about 1:10 and about 1:20, or between about 1:5 and about 1:5000. Generally, increasing the proportion of the gas flow that is the inhibiting species, such as NF₃, increases the inhibition effect and/or etch component of exposing the substrate to an inhibition plasma.

As discussed above, ALD is used to fill the features. ALD is a technique that sequentially deposits thin layers of material. ALD processes use surface-mediated deposition reactions to deposit films on a layer-by-layer basis in cycles. The concept of an ALD “cycle” is relevant to the discussion of various embodiments herein. Generally, a cycle is the minimum set of operations used to perform a surface deposition reaction one time. The result of one cycle is the production of at least a partial silicon-containing film layer on a substrate surface. Typically, an ALD cycle includes operations to deliver and adsorb at least one reactant to the substrate surface, and then react the adsorbed reactant with one or more reactants to form the partial layer of film. The cycle may include certain ancillary operations such as sweeping one of the reactants or byproducts and/or treating the partial film as deposited. Generally, a cycle contains one instance of a unique sequence of operations.

As an example, an ALD cycle may include the following operations: (i) delivery/adsorption of a precursor, (ii) purging of the precursor from the chamber, (iii) delivery of a second reactant and optional plasma ignition, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface-active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed species of the first precursor. When a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas or nitrogen-containing gas, is introduced to the chamber so that some of these molecules react with the first precursor adsorbed on the surface. In some processes, the second reactant reacts immediately with the adsorbed first precursor. In other embodiments, the second reactant reacts only if a source of activation such as plasma is applied temporally. The chamber may then be evacuated again to remove unbound second reactant molecules. As described above, in some embodiments the chamber may not be completely evacuated. Additional ALD cycles may be used to build film thickness.

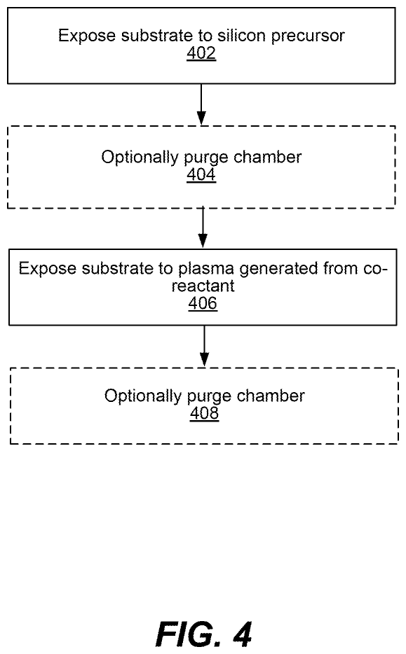

FIG. 4 presents a process flow diagram for a single plasma enhanced ALD cycle that may be implemented as part of operation 103 to deposit a conformal layer or for any of the other ALD operations shown in FIG. 3. In an operation 402, the substrate is exposed to a silicon-containing precursor, to adsorb the precursor onto the surface of the feature. This operation may be self-limiting. In some embodiments, the precursor adsorbs to less than all the active sites on the surface of the feature. In an operation 404, the process chamber is optionally purged to remove any unadsorbed silicon-containing precursors. In an operation 406, the substrate is exposed to a plasma generated from a co-reactant. Examples include oxygen-containing species (such as, O₂ and/or N₂O) to form a silicon oxide layer, nitrogen-containing species (such as, N₂ or NH₃ to form a silicon nitride layer, etc. In operation 408, the process chamber is optionally purged to remove byproducts from the reaction between the silicon-containing precursor and the oxidant. Operations 402 through 408 repeated for a number of cycles to deposit the silicon-containing layer to a desired thickness in the feature.

It should be noted that the processes described herein are not limited to a particular reaction mechanism. Thus, the process described with respect to FIG. 3 includes all deposition processes that use sequential exposures to silicon-containing reactants and conversion plasmas, including those that are not strictly self-limiting. The process includes sequences in which one or more gases used to generate a plasma is continuously flowed throughout the process with intermittent plasma ignitions.

For depositing silicon oxide, one or more silicon-containing precursors may be used. In some examples, silicon-containing precursors can include silanes (e.g., SiH₄), polysilanes (H₃Si—(SiH₂)ₙ—SiH₃) where n≥1, organosilanes, halogenated silanes, aminosilanes, alkoxysilanes, and the like. Organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino) silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di-isopropylaminosilane (DIPAS), di-sec-butylaminosilane (DSBAS), SiH₂[N(CH₂CH₃)₂]₂ (BDEAS) and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In some implementations silicon-containing precursors may include siloxanes or amino-group-containing siloxanes. In some embodiments, siloxanes used herein may have a formula of X(R¹)ₐSi—O—Si(R²)_{b}Y, where a and b are integers from 0 to 2, and X and Y independently can be H or NR³R⁴, where each of R1, R2, R3 and R4 is hydrogen, unbranched alkyl, branched alkyl, saturated heterocyclic, unsaturated heterocyclic groups, or combinations thereof. In some embodiments, when at least one X or Y is NR³R⁴, R³ and R⁴, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1,1,3,3,3,-pentamethyl disiloxane, 1 dipropylamino-1,1,3,3,3,-pentamethyl disiloxane, 1-di-n-butylamino-1,1,3,3,3,-pentamethyl disiloxane, 1-di-sec-butylamino-1,1,3,3,3,-pentamethyl disiloxane, 1-N-methylethylamino 1,1,3,3,3,-pentamethyl disiloxane, 1-N-methylpropylamino-1,1,3,3,3,-pentamethyl disiloxane, 1 N-methylbutylamino-1,1,3,3,3,-pentamethyl disiloxane, 1-t-butylamino-1,1,3,3,3,-pentamethyl disiloxane, 1-piperidino-1,1,3,3,3,-pentamethyl disiloxane, 1-dimethylamino-1,1-dimethyl disiloxane, 1-diethylamino-1,1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-sec butylamino-1,1-dimethyl disiloxane, 1-N-methylethylamino-1,1-dimethyl disiloxane, 1-N methylpropylamino-1,1-dimethyl disiloxane, 1-N-methylbutylamino-1,1-dimethyl disiloxane, 1 piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino-disiloxane, 1-piperidino-disiloxane, 1-t-butylamino disiloxane, and 1-dimethylamino-1,1,5,5,5,-pentamethyl disiloxane.

Where a deposited film includes oxygen, an oxygen-containing reactant may be used. Examples of oxygen-containing reactants include, but are not limited to, oxygen (O₂), ozone (O₃), nitrous oxide (N₂O), nitric oxide (NO), nitrogen dioxide (NO₂), dinitrogen trioxide (N₂O₃), dinitrogen tetroxide (N₂O₄), dinitrogen pentoxide (N₂O₅), carbon monoxide (CO), carbon dioxide (CO₂), sulfur oxide (SO), sulfur dioxide (SO₂), oxygen-containing hydrocarbons (CₓH_{y}O₂), water (H₂O), formaldehyde (CH₂O), carbonyl sulfide (COS), mixtures thereof, etc.

Where a deposited film includes nitrogen, a nitrogen-containing reactant may be used. A nitrogen-containing reactant contains at least one nitrogen, for example, nitrogen (N₂), ammonia (NH₃), hydrazine (N₂H₄), amines (e.g., amines bearing carbon) such as methylamine (CH₅N), dimethylamine ((CH₃)₂NH), ethylamine (C₂H₅NH₂), isopropylamine (C₃H₉N), t-butylamine (C₄H₁₁N), di-t-butylamine (C₈H₁₉N), cyclopropylamine (C₃H₅NH₂), sec-butylamine (C₄H₁₁N), cyclobutylamine (C₄H₇NH₂), isoamylamine (C₅H₁₃N), 2-methylbutan-2-amine (C₅H₁₃N), trimethylamine (C₃H₉N), diisopropylamine (C₆H₁₅N), diethylisopropylamine (C₇H₁₇N), di-t-butylhydrazine (C₈H₂ON₂), as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants. Other examples include NₓO_{y} compounds such as nitrous oxide (N₂O), nitric oxide (NO), nitrogen dioxide (NO₂), dinitrogen trioxide (N₂O₃), dinitrogen tetroxide (N₂O₄) and/or dinitrogen pentoxide (N₂O₅).

Another aspect of this disclosure relates to filling feature having reentrant structures. As described above, inhibition plasmas may be used to inhibit deposition near the top of a feature with less or no inhibition near the bottom of the feature, thus facilitating a bottom-up fill mechanism when using ALD processes. However, in some embodiments the inhibition plasma does not completely inhibit above a certain depth; rather, the inhibition effect tapers throughout the depth of the feature. Thus, some deposition may occur on the sidewalls near the bottom of the feature despite some amount of inhibition. This may not be a concern where the profile of the feature is substantially straight, as the bottom-up fill mechanism may proceed faster than any pinch off could occur from sidewall growth near the bottom of the feature. However, in implementations where the gap includes a reentrant structure, the sidewall growth may proceed sufficiently to cause a pinch off before the gap below the reentrancy can be sufficiently filled.

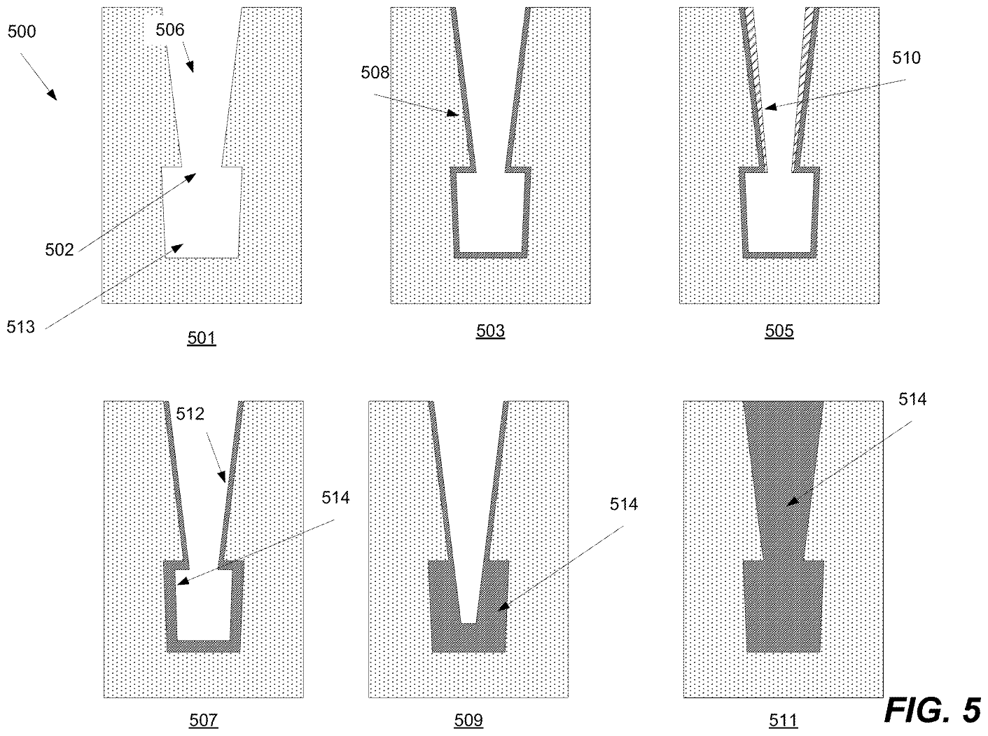

FIG. 5 presents a series of diagrams illustrating a process for filling features having re-entrant structures. At 501, a structure 500 has a gap 506 to be filled with dielectric material, a pinch point 502, and a re-entrant opening 513. In some embodiments, the ratio of the width of the feature at the pinch point 502 to the width of the feature below the pinch point 502 is at least about 5:1, or at least about 10:1. In some embodiments, the pinch point 502 is at a height from the bottom of the feature which is about 40% of the total height of the feature, or less than about 50% of the total height of the feature. In some embodiments, the total feature depth is about 3 microns, or less than about 3 microns. Attempting to fill this feature with a bottom-up fill mechanism using an inhibition plasma may result in a very slow fill or a void in reentrant opening 513 due to a pinch off at the pinch point 502 resulting from sidewall deposition. If the structure is exposed to the inhibition plasma to completely inhibit at pinch point 502, the inhibition plasma will also reach below pinch point 502, preventing deposition in the reentrant opening 513 or significantly slowing the deposition rate. Alternatively, if the amount of inhibition is reduced, the pinch point 502 fills before the reentrant opening 513 can fill, causing a pinch off and void to occur.

To address this issue, provided is a process to etch back at the pinch point 502 without etching, with reduced etching, or with deposition in the reentrant opening 513. In some embodiments, an inhibition plasma may have an etch component under certain process conditions, as described above. As noted above, increasing the power of the plasma during inhibition operations causes the inhibition species to form ions that have sufficient energy to etch the substrate. ALD deposition as discussed herein may also be a plasma enhanced ALD, such that a plasma is ignited that has similar properties as the plasma used for inhibition operations. Furthermore, after an inhibition operation the chamber and/or structure may have small amounts of inhibiting species, e.g., fluorine, that, when a plasma is ignited for the ALD operation, may become ions that bombard and etch the substrate. This effect may be similar to an atomic layer etch (ALE) process, where some of the species left from the inhibition surface treatment etch the substrate when a plasma is first ignited following the inhibition operation. In some examples, this effect is typically only observed within the initial ALD cycles (For example, for the first 1 or 2 ALD cycles of the total ALD cycles) after an inhibition treatment, after which deposition occurs for subsequent ALD cycles. Furthermore, this etch effect may be tuned to not occur below the pinch point 502, allowing the film to grow below the pinch point with a reduced risk of pinch off.

An ALE-type etch from a first ALD cycle following an inhibition treatment may be preferable over a discrete etch step. In particular, a separate etch operation does not need to be performed, increasing throughput, particularly as the inhibition and ALD operations may be performed in the same chamber. Furthermore, a discrete etch may be harder to tune to etch at and above the pinch point without etching in the reentrant structure that is to be filled. A discrete etch may also etch more above the pinch point, causing damage to the underlying layers.

Thus, in some implementations, an ALE-type etch may be used to etch back deposition at the pinch point while allowing for deposition below the pinch point. Returning to FIG. 5, at 503 a conformal layer 508 is deposited. Conformal layer 508 may act as a sacrificial layer so that a subsequent etch affects conformal layer 508 rather than the underlying layer. In some embodiments conformal layer 508 is the same dielectric material as the dielectric material to fill the feature. In other embodiments conformal layer 508 may be a protective liner that has lower selectivity than the dielectric material to the inhibition plasma to inhibit etching of the underlying layers. Conformal layer 508 may be any material described herein for a conformal layer.

At 505, the structure is exposed to an inhibition plasma to form an inhibition layer 510. Layer 510 may taper, having a greater inhibition effect near the top of the feature compared to the pinch point 502.

At 507, one or more ALD cycles are performed. Below the pinch point 502, the ALD cycles cause a deposition of dielectric material 514 such that the feature is partially filled. Above the pinch point 502, some of the inhibition layer 510 is ionized to cause a slight etch of the conformal layer 508, resulting in the sidewalls having no growth or even a slight etch back compared to the conformal layer at 503. In various implementations a single ALD cycle may cause a deposition below the pinch point and an etch above the pinch point. In other embodiments, the first ALD cycle may etch above the pinch point but not etch or deposit below the pinch point. Then, in a second ALD cycle dielectric material may deposit conformally or with a taper from bottom to top (as a result of the surface treatment to inhibit deposition). As the first ALD cycle caused an etch at and above the pinch point 502, the additional ALD cycles do not cause a net growth in sidewall thickness at the pinch point following a single growth cycle but do cause a net growth in deposited dielectric material below the pinch point 502.

The operations shown at 505 and 507 may be repeated multiple times to gradually deposit dielectric material below the pinch point 502.

At 509 the gap below the pinch point 502 may be sufficiently filled with dielectric material 514 that the reentrant feature is no longer apparent from the geometry of the remaining gap. In such embodiments the process may be adjusted to use a bottom-up fill mechanism as described herein without etching at and above the pinch point. At 511 the feature is completely filled with smaller or no voids in or near the reentrant opening 513.

Returning to FIG. 3, the process flow of FIG. 3 may be performed to accomplish an ALE-type etch as described herein. Most of the operations may be performed as discussed above except for blocks 308 and 310. Referring to blocks 308 and 310, the inhibition plasma and ALD fill may be tailored to control fill below a reentrancy and inhibit pinch off. In some embodiments, the inhibition plasma used for filling re-entrant structures may be performed using the same parameters for power, process gas flow, temperature, or pressure as described in relation to sidewall smoothing. However, the duration of exposing the substrate to an inhibition plasma may be between about 0.1 and about 0.2 seconds, between about 0.25 and about 0.5 seconds, or less than about 1 second. In some embodiments, increasing power or flow rate during the initial ALD cycles may increase the amount of etch, which may be desirable to etch the re-entrant structure faster, decreasing the duration of the ALE-type etch process and thus increasing throughput. The lower exposure time is to avoid inhibiting below the re-entrant structure and may also be based on using fewer ALD cycles between inhibition treatments. In some embodiments, the RF power during the ALD cycles to achieve an ALE-type etch may be the same as RF powers previously described herein. In some embodiments, the RF power is between about 1000 W and about 3000 W.

In some embodiments one ALD cycle is performed between inhibition treatments. In other embodiments 1, 2, 3, or 4 ALD cycles are performed between inhibition treatments. In some embodiments, between 1 and 4 ALD cycles are performed between inhibition treatments. In some embodiments, less than about 10 ALD cycles are performed between inhibition treatments. The number of ALD cycles to be performed may depend on the rate of deposition below and at the pinch point. As fewer ALD cycles reduce throughput, the number of ALD cycles may be selected based on having no net deposition per growth cycle at the pinch point while depositing below the pinch point in the reentrant structure. In various embodiments the first ALD cycle etches to a target depth within the feature (e.g., the pinch point) without etching below the target depth, while the following ALD cycles deposit within the feature in a bottom-up mechanism. By having relatively few ALD cycles that deposit compared to the first ALE-type cycle, the bottom of the feature may fill without a pinch off occurring as a result of a reentrant structure filling above a pinch point of the reentrant structure.

### Apparatus

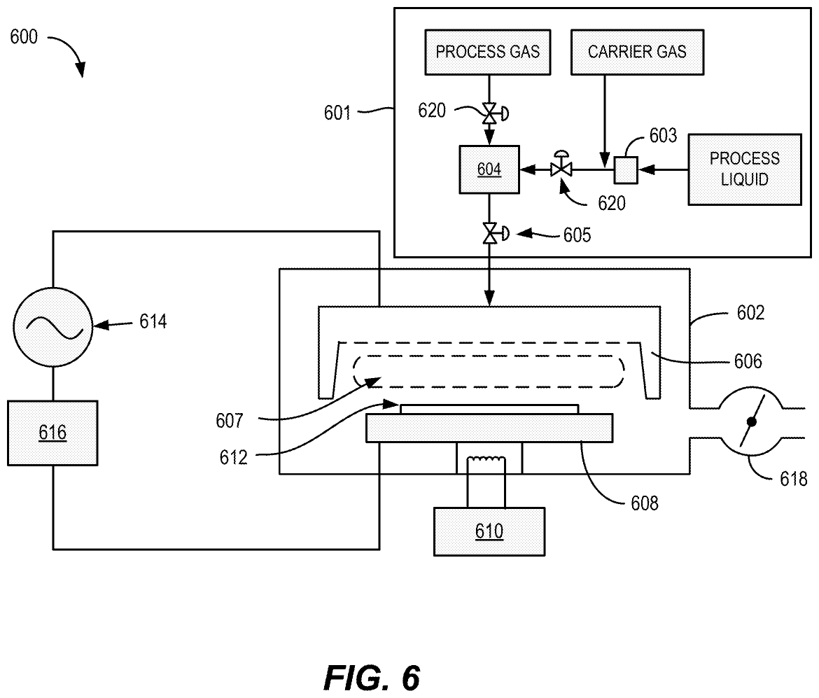

FIG. 6 schematically shows an embodiment of a process station 600 that may be used to deposit material using atomic layer deposition (ALD) and/or chemical vapor deposition (CVD), either of which may be plasma enhanced. For simplicity, the process station 600 is depicted as a standalone process station having a process chamber body 602 for maintaining a low-pressure environment. However, it will be appreciated that a plurality of process stations 600 may be included in a common process tool environment. Further, it will be appreciated that, in some embodiments, one or more hardware parameters of process station 600, including those discussed in detail below, may be adjusted programmatically by one or more computer controllers 650.

Process station 600 fluidly communicates with reactant delivery system 601 for delivering process gases to a distribution showerhead 606. Reactant delivery system 601 includes a mixing vessel 604 for blending and/or conditioning process gases for delivery to showerhead 606. One or more mixing vessel inlet valves 620 may control introduction of process gases to mixing vessel 604. Similarly, a showerhead inlet valve 605 may control introduction of process gasses to the showerhead 606. In some embodiments, an inhibitor or other gas may be directly delivered to the chamber body 602. One or more mixing vessel inlet valves 720 may control introduction of process gases to mixing vessel 604. These valves may be controlled depending on whether a process gas, inhibition gas, or carrier gas may be turned on during various operations. In some embodiments, an inhibition gas may be generated by using an inhibition liquid and vaporizing using a heated vaporizer.

As an example, the embodiment of FIG. 6 includes a vaporization point 603 for vaporizing liquid reactant to be supplied to mixing vessel 604. In some embodiments, vaporization point 603 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 603 may be heat traced. In some examples, mixing vessel 604 may also be heat traced. In one non-limiting example, piping downstream of vaporization point 603 has an increasing temperature profile extending from approximately 100° C. to approximately 150° C. at mixing vessel 604.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel 604. In another scenario, a liquid injector may be mounted directly to showerhead 606.

In some embodiments, a liquid flow controller (LFC) upstream of vaporization point 603 may be provided for controlling a mass flow of liquid for vaporization and delivery to process station 600. For example, the liquid flow controller may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 606 distributes process gases toward substrate 612. In the embodiment shown in FIG. 6, substrate 612 is located beneath showerhead 606, and is shown resting on a pedestal 608. It will be appreciated that showerhead 606 may have any suitable shape, and may have any suitable number and arrangement of ports for distributing processes gases to substrate 612.

In some embodiments, a microvolume 607 is located beneath showerhead 606.

Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 608 may be raised or lowered to expose substrate 612 to microvolume 607 and/or to vary a volume of microvolume 607. For example, in a substrate transfer phase, pedestal 608 may be lowered to allow substrate 612 to be loaded onto pedestal 608. During a deposition process phase, pedestal 608 may be raised to position substrate 612 within microvolume 607. In some embodiments, microvolume 607 may completely enclose substrate 612 as well as a portion of pedestal 608 to create a region of high flow impedance during a deposition process.

Optionally, pedestal 608 may be lowered and/or raised during portions the deposition process to modulate process pressure, reactant concentration, etc., within microvolume 607. In one scenario where process chamber body 602 remains at a base pressure during the deposition process, lowering pedestal 608 may allow microvolume 607 to be evacuated. Example ratios of microvolume to process chamber volume include, but are not limited to, volume ratios between 1:600 and 1:10. It will be appreciated that, in some embodiments, pedestal height may be adjusted programmatically by a suitable computer controller.

In another scenario, adjusting a height of pedestal 608 may allow a plasma density to be varied during plasma activation and/or treatment cycles included in the deposition process. At the conclusion of the deposition process phase, pedestal 608 may be lowered during another substrate transfer phase to allow removal of substrate 612 from pedestal 608.

While the example microvolume variations described herein refer to a height-adjustable pedestal, it will be appreciated that, in some embodiments, a position of showerhead 606 may be adjusted relative to pedestal 608 to vary a volume of microvolume 607. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers.

Returning to the embodiment shown in FIG. 6, showerhead 606 and pedestal 608 electrically communicate with RF power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Examples of suitable powers are included above. Likewise, RF power supply 614 may provide RF power of any suitable frequency. In some embodiments, RF power supply 614 may be configured to control high- and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 608 may be temperature controlled via heater 610.

Further, in some embodiments, pressure control for deposition process station 600 may be provided by butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to process station 600.

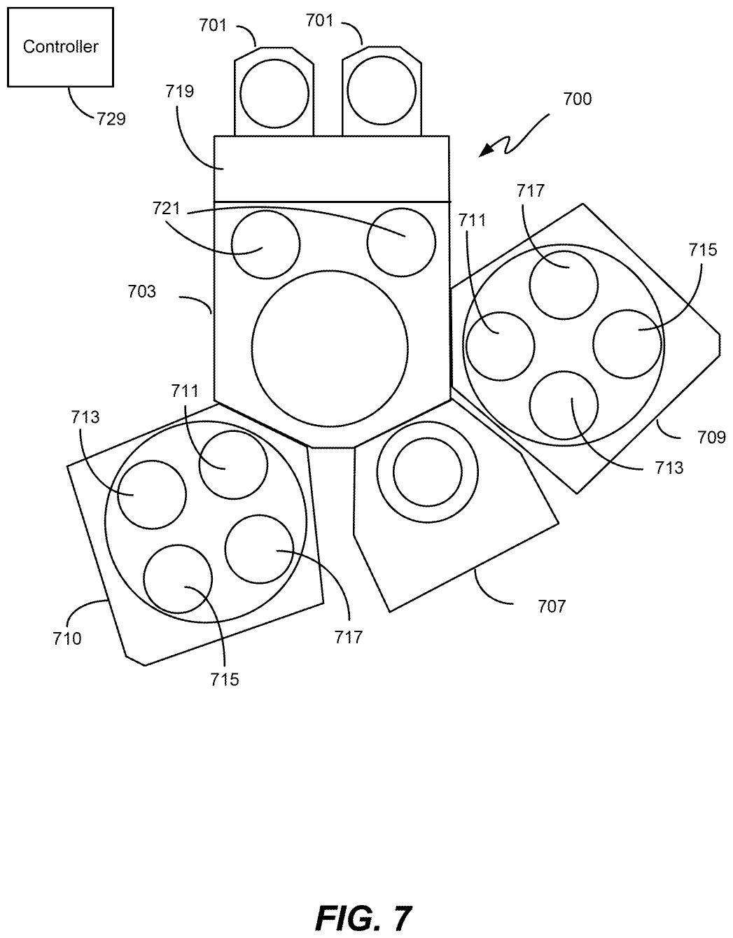

FIG. 7 is a block diagram of a processing system suitable for conducting thin film deposition processes in accordance with certain embodiments. The system 700 includes a transfer module 703. The transfer module 703 provides a clean, pressurized environment to minimize risk of contamination of substrates being processed as they are moved between various reactor modules. Mounted on the transfer module 703 are two multi-station reactors 709 and 710, each capable of performing atomic layer deposition (ALD) and/or chemical vapor deposition (CVD) according to certain embodiments. Reactors 709 and 710 may include multiple stations 711, 713, 715, and 717 that may sequentially or non-sequentially perform operations in accordance with disclosed embodiments. The stations may include a heated pedestal or substrate support, one or more gas inlets or showerhead or dispersion plate.

Also mounted on the transfer module 703 may be one or more single or multi-station modules 707 capable of performing plasma or chemical (non-plasma) pre-cleans, or any other processes described in relation to the disclosed methods. The module 707 may in some cases be used for various treatments to, for example, prepare a substrate for a deposition process. The module 707 may also be designed/configured to perform various other processes such as etching or polishing. The system 700 also includes one or more wafer source modules 701, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In various embodiments, a system controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all of the activities of the deposition apparatus. The system controller 729 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 729 may be employed in some embodiments.

Typically there will be a user interface associated with the controller 729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 729. The signals for controlling the process are output on the analog and digital output connections of the deposition apparatus 700.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller, such as controller 650 or 729, is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 729, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

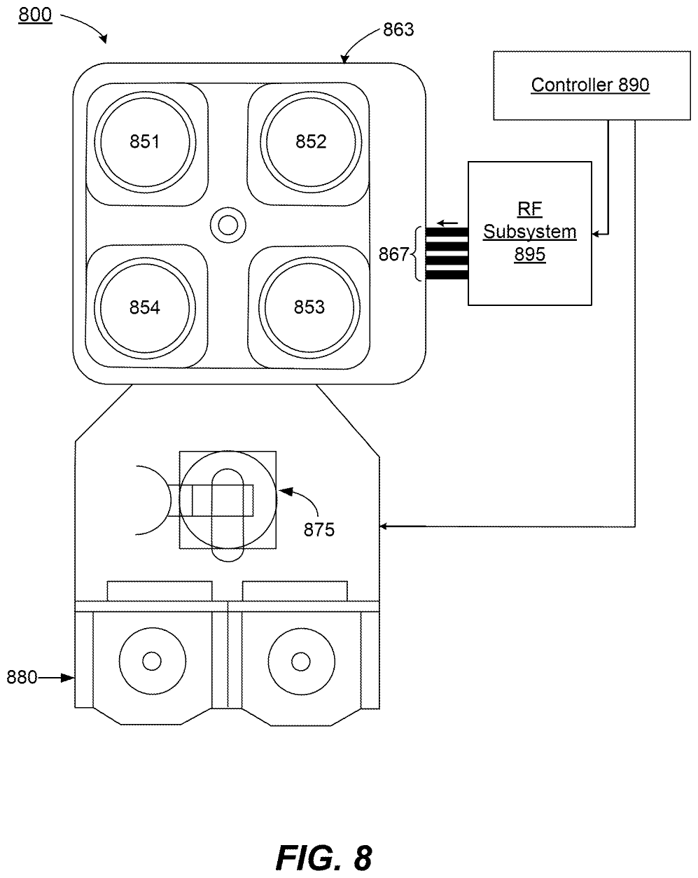

It may be appreciated that a plurality of process stations may be included in a multi-station processing tool environment, such as shown in FIG. 8, which depicts a schematic view of an embodiment of a multi-station processing tool. Processing apparatus 800 employs an integrated circuit fabrication chamber 863 that includes multiple fabrication process stations, each of which may be used to perform processing operations on a substrate held in a wafer holder, such as a pedestal, at a particular process station. In the embodiment of FIG. 8, the integrated circuit fabrication chamber 863 is shown having four process stations 851, 852, 853, and 854. Other similar multi-station processing apparatuses may have more or fewer process stations depending on the implementation and, for example, a desired level of parallel wafer processing, size/space constraints, cost constraints, etc. Also shown in FIG. 8 is substrate handler robot 875, which may operate under the control of system controller 890, configured to move substrates from a wafer cassette (not shown in FIG. 8) from loading port 880 and into integrated circuit fabrication chamber 863, and onto one of process stations 851, 852, 853, and 854.

FIG. 8 also depicts an embodiment of a system controller 890 employed to control process conditions and hardware states of processing apparatus 800. System controller 890 may include one or more memory devices, one or more mass storage devices, and one or more processors, as described herein.

RF subsystem 895 may generate and convey RF power to integrated circuit fabrication chamber 863 via radio frequency input ports 867. In particular embodiments, integrated circuit fabrication chamber 863 may comprise input ports in addition to radio frequency input ports 867 (additional input ports not shown in FIG. 8). Accordingly, integrated circuit fabrication chamber 863 may utilize 8 RF input ports. In particular embodiments, process stations 851-854 of integrated circuit fabrication chamber 165 may each utilize first and second input ports in which a first input port may convey a signal having a first frequency and in which a second input port may convey a signal having a second frequency. Use of dual frequencies may bring about enhanced plasma characteristics.

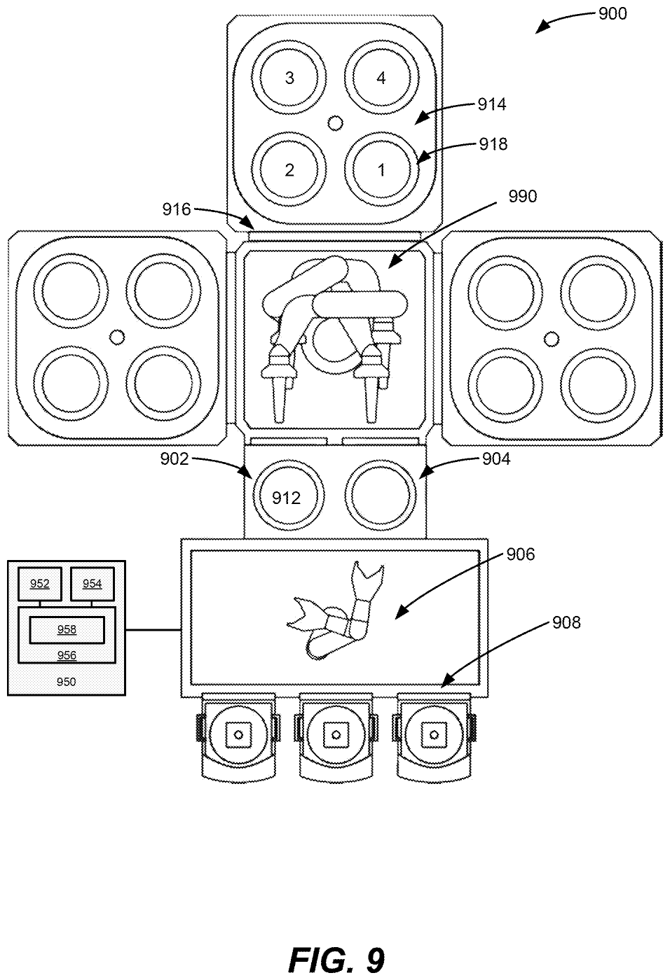

As described above, one or more process stations may be included in a multi-station processing tool. FIG. 9 shows a schematic view of an embodiment of a multi-station processing tool 900 with an inbound load lock 902 and an outbound load lock 904, either or both of which may comprise a remote plasma source. A robot 906, at atmospheric pressure, is configured to move substrates or wafers from a cassette loaded through a pod 908 into inbound load lock 902 via an atmospheric port. A substrate is placed by the robot 906 on a pedestal 912 in the inbound load lock 902, the atmospheric port is closed, and the load lock is pumped down. Where the inbound load lock 902 comprises a remote plasma source, the substrate may be exposed to a remote plasma treatment in the load lock prior to being introduced into a processing chamber 914. Further, the substrate also may be heated in the inbound load lock 902 as well, for example, to remove moisture and adsorbed gases. Next, a chamber transport port 916 to processing chamber 914 is opened, and another robot 990 places the substrate into the reactor on a pedestal of a first station shown in the reactor for processing. While the embodiment depicted in FIG. 9 includes load locks, it will be appreciated that, in some embodiments, direct entry of a substrate into a process station may be provided. In various embodiments, the soak gas is introduced to the station when the substrate is placed by the robot 906 on the pedestal 912.

The depicted processing chamber 914 comprises four process stations, numbered from 1 to 4 in the embodiment shown in FIG. 9. Each station has a heated pedestal (shown at 918 for station 1), and gas line inlets. It will be appreciated that in some embodiments, each process station may have different or multiple purposes. For example, in some embodiments, a process station may be switchable between an ALD and PEALD process mode. Additionally or alternatively, in some embodiments, processing chamber 914 may include one or more matched pairs of ALD and plasma-enhanced ALD process stations. While the depicted processing chamber 914 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 9 depicts an embodiment of a wafer handling system 990 for transferring substrates within processing chamber 914. In some embodiments, wafer handling system 990 may transfer substrates between various process stations and/or between a process station and a load lock. It will be appreciated that any suitable wafer handling system may be employed. Non-limiting examples include wafer carousels and wafer handling robots. FIG. 9 also depicts an embodiment of a system controller 950 employed to control process conditions and hardware states of process tool 900. System controller 950 may include one or more memory devices 956, one or more mass storage devices 954, and one or more processors 952. Processor 952 may include a CPU or computer, analog and/or digital input/output connections, stepper motor controller boards, etc. In some embodiments, system controller 950 includes machine-readable instructions for performing operations such as those described herein.

In some embodiments, system controller 950 controls the activities of process tool 900. System controller 950 executes system control software 958 stored in mass storage device 954, loaded into memory device 956, and executed on processor 952. Alternatively, the control logic may be hard coded in the system controller 950. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 958 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 900. System control software 958 may be configured in any suitable way. For example, various process tool component subroutines or control objects may be written to control operation of the process tool components used to carry out various process tool processes. System control software 958 may be coded in any suitable computer readable programming language.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method, comprising:
providing a substrate having a structure with a gap;
depositing a conformal layer of a first dielectric material in the gap of the structure; and
performing a first set of one or more cycles of:
(a) exposing the substrate to a plasma comprising halogen species to etch the first dielectric material on a first portion of the gap; and
(b) after (a), depositing a second dielectric material in the gap; and
after performing the first set of one or more cycles, depositing additional second dielectric material in the gap.

2. The method of claim 1, wherein during (a) exposing the substrate to a plasma comprising halogen species inhibits deposition on a second portion of the gap.

3. The method of claim 1, wherein depositing the second dielectric material comprises a plasma enhanced atomic layer deposition (ALD) process.

4. The method of claim 1, wherein depositing additional second dielectric material in the gap comprises performing one or more cycles of:
exposing the substrate to a plasma comprising halogen species to inhibit dielectric material on a second portion of the gap; and
after exposing the substrate to the plasma comprising halogen species, depositing second dielectric material in the gap.

5. The method of claim 4, wherein the second portion is near the top of the gap.

6. The method of claim 1, wherein the conformal layer is a silicon-containing film.

7. The method of claim 1, wherein the conformal layer is an oxide film.

8. The method of claim 1, wherein the first dielectric material and the second dielectric material are silicon dioxide.

9. The method of claim 1, wherein the plasma comprising halogen species is generated from fluorine-containing gas.

10. The method of claim 9, wherein the plasma comprising halogen species is generated from nitrogen-containing gas.

11. The method of claim 1, wherein the structure comprises layers of different materials and the gap are conformally covered by a layer of poly silicon.

12. The method of claim 1, wherein the gap has sidewalls having a roughness of at least about 0.5 nm.

13. The method of claim 1, wherein exposing the substrate to a plasma comprising halogen species reduces a roughness of one or more sidewalls of the gap.

14. The method of claim 1, wherein the plasma has a power of at least about 250 W per substrate.

15. The method of claim 1, wherein the plasma has a power of between about 625 W and about 1500 W per substrate.

16. The method of claim 1, wherein a duration of exposing the substrate to the plasma is at least 20 seconds.

17. The method of claim 1, wherein the conformal layer is at least about 10 Angstroms thick.

18. The method of claim 1, wherein depositing a conformal layer and the performing the first set of one or more cycles are performed in the same chamber.

19. The method of claim 1, wherein the gap comprises a re-entrant feature.

20. The method of claim 1, wherein depositing second dielectric material in the gap comprises two or more cycles of an ALD process, wherein at least the first ALD cycle of the two or more cycles etches dielectric material in the second portion of the gap.

21. A method, comprising:
providing a substrate having a gap that includes a re-entrant structure;
depositing a conformal layer of a first dielectric material in the gap; and
performing a first set of one or more cycles of:
(a) exposing the substrate to a plasma comprising halogen species to inhibit deposition on a portion of the gap above the re-entrant structure; and
(b) depositing a second dielectric material in the gap, wherein during (b) the portion of the gap above the re-entrant structure is etched.

22. The method of claim 21, wherein (a) is performed for between about 0.1 and about 0.2 seconds.

23. The method of claim 21, wherein the re-entrant structure has a first portion and a second portion, and a ratio of a width of the first portion and a width of the second portion is at least about 5:1.

24. The method of claim 21, wherein a first portion of the re-entrant structure is the narrowest portion of the re-entrant structure, and wherein the first portion is at a height from the bottom of the gap of less than about 50% of the total height of the gap.

25. The method of claim 21, wherein (b) comprises a plasma enhanced atomic layer deposition (ALD) process.

26. The method of claim 21, wherein during (b) halogen species etch dielectric material in the gap but do not etch in the re-entrant structure.

27. The method of claim 21, wherein during (a) halogen species are adsorbed on the portion of the gap, and during (b) the adsorbed halogen species etch dielectric material in the gap.

28. The method of claim 21, wherein during (b) a plasma is ignited having a power between about 1000 W and about 3000 W.

29. The method of claim 21, further comprising performing a second set of one or more cycles to fill the gap with dielectric material, wherein the second set of one or more cycles is performed after partially filling the re-entrant structure with dielectric material.
